(19) United States
(12) Patent Application Publication
(10) Pub. No.: US 2026/0282812 A1
(43) Pub. Date: Sep. 17, 2026

(54) CONTROLLING METHOD FOR SEMICONDUCTOR PROCESS AUXILIARY APPARATUS, CONTROL ASSEMBLY AND MANUFACTURING SYSTEM

(71) Applicant: UNITED MICROELECTRONICS CORP., Hsinchu (TW)

(72) Inventors: Chih-Chung KUO, Tainan City (TW); Yung-Chieh KUO, Hsinchu County (TW); Cheng-Tai PENG, Hsinchu County (TW); Min-Wei TSAI, Tainan City (TW); Sheng-Ming WANG, Kaohsiung City (TW); Jui-Hung LEE, Kaohsiung City (TW); Ke-Wei WEI, Tainan City (TW); Ping-Yi LU, Tainan City (TW); Shi-Hao WANG, Taichung City (TW); Chih-Hsiang HSIAO, Hsinchu City (TW)

(21) Appl. No.: 19/684,216

(22) Filed: May 21, 2026

Related U.S. Application Data
(62) Division of application No. 18/395,777, filed on Dec. 26, 2023.

(30) Foreign Application Priority Data
Nov. 2, 2023 (CN) 202311446708.5

(51) Int. Cl. H10P 72/00

(52) U.S. Cl. CPC H10P 72/0604; H10P 72/0402; H10P 72/0468

(57) ABSTRACT

A controlling method for semiconductor process auxiliary apparatus, a control assembly and a manufacturing system are provided. The controlling method includes the following steps. At least one manufacturing parameter of a semiconductor manufacturing processing apparatus are obtained. An energy adjusting signal is generated according to the manufacturing parameter. An auxiliary apparatus controlling signal is generated according to the energy adjusting signal. The semiconductor process auxiliary apparatus is controlled according to the semiconductor auxiliary apparatus controlling signal.

This is a divisional application of U.S. application Ser. No. 18/395,777, filed Dec. 26, 2023, which claims the benefit of People's Republic of China application Serial No. 202311446708.5, filed Nov. 2, 2023, the disclosure of which is incorporated by reference herein in its entirety.

### TECHNICAL FIELD

The disclosure relates in general to a controlling method, an electric assembly and an electric system, and more particularly to a controlling method for semiconductor process auxiliary apparatus, a control assembly and a manufacturing system.

### BACKGROUND

With the advancement of semiconductor technology, the manufacturing procedures of semiconductors are becoming more and more complicated. Wafer must be performed variety of semiconductor manufacturing process apparatuses to perform thousands to tens of thousands of processes to complete the production of dies.

During the operation of the semiconductor manufacturing process apparatus, it is necessary to perform gas extraction, gas purification, heating, water injection and other actions through the semiconductor process auxiliary apparatus to achieve the pressure, gas concentration, temperature, cleanliness and other requirements in the chamber.

However, in traditional, during the semiconductor manufacturing, the semiconductor process auxiliary apparatus will continue to operate, resulting in a waste of energy or materials.

### SUMMARY

The disclosure is directed to a controlling method for semiconductor process auxiliary apparatus, a control assembly and a manufacturing system. During the operation of the semiconductor manufacturing process apparatus, an energy adjusting signal could be generated based on the manufacturing parameters of the semiconductor manufacturing process apparatus. Then, a corresponding auxiliary apparatus controlling signal is generated according to the energy adjusting signal. The semiconductor process auxiliary apparatus is controlled according to the auxiliary apparatus controlling signal, so that the semiconductor process auxiliary apparatus will not use 100% of the energy or materials all the time. Therefore, the effect of saving energy or materials is achieved.

According to one embodiment, a controlling method for at least one semiconductor process auxiliary apparatus is provided. The controlling method includes: obtaining at least one manufacturing parameter of a semiconductor manufacturing process apparatus; generating an energy adjusting signal according to the at least one manufacturing parameter; generating an auxiliary apparatus controlling signal according to the energy adjusting signal; and controlling the at least one semiconductor process auxiliary apparatus according to the auxiliary apparatus controlling signal.

According to another embodiment, a control assembly is provided. The control assembly is for controlling at least one semiconductor process auxiliary apparatus. The control assembly includes an energy-saving trigger analyzing unit and an energy-saving control unit. The energy-saving trigger analyzing unit is used for generating an energy adjusting signal according to at least one manufacturing parameter of a semiconductor manufacturing process apparatus. The energy-saving control unit is used for generating an auxiliary apparatus controlling signal according to the energy adjusting signal, and used for controlling the at least one semiconductor process auxiliary apparatus according to the auxiliary apparatus controlling signal.

According to an alternative embodiment, a manufacturing system is provided. The manufacturing system includes a semiconductor manufacturing process apparatus, at least one semiconductor process auxiliary apparatus and a control assembly. The semiconductor manufacturing process apparatus has at least one manufacturing parameter. The control assembly includes an energy-saving trigger analyzing unit and an energy-saving control unit. The energy-saving trigger analyzing unit is used for generating an energy adjusting signal according to the at least one manufacturing parameter of the semiconductor manufacturing process apparatus. The energy-saving control unit is used for generating an auxiliary apparatus controlling signal according to the energy adjusting signal, and used for controlling the at least one semiconductor process auxiliary apparatus according to the auxiliary apparatus controlling signal.

### BRIEF DESCRIPTION OF THE DRAWINGS

FIG. 1 illustrates a semiconductor manufacturing process apparatus of a manufacturing system.

FIG. 2 shows a block diagram of the manufacturing system according to one embodiment.

FIG. 3 illustrates a flow chart of a controlling method for a semiconductor process auxiliary apparatus according to an embodiment.

FIG. 4 shows a schematic diagram of the semiconductor manufacturing process apparatus according to an embodiment.

FIG. 5A illustrates a detailed flow chart of step S120 according to an embodiment.

FIG. 5B illustrates a detailed flow chart of the step S120 according to another embodiment.

FIG. 6 shows a detailed schematic diagram of an energy-saving control unit according to one embodiment.

FIGS. 7A to 7B illustrate the energy-saving control of the nitrogen regulator and the pump.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

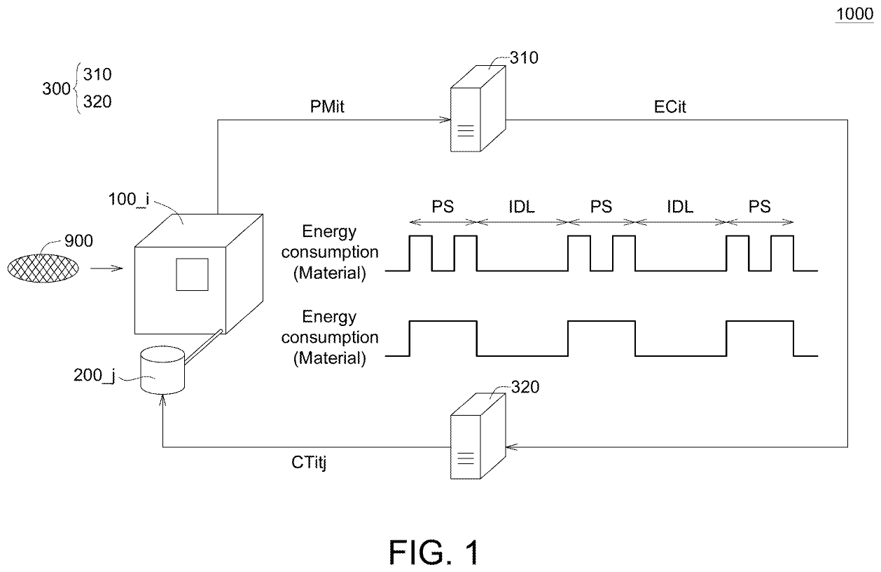

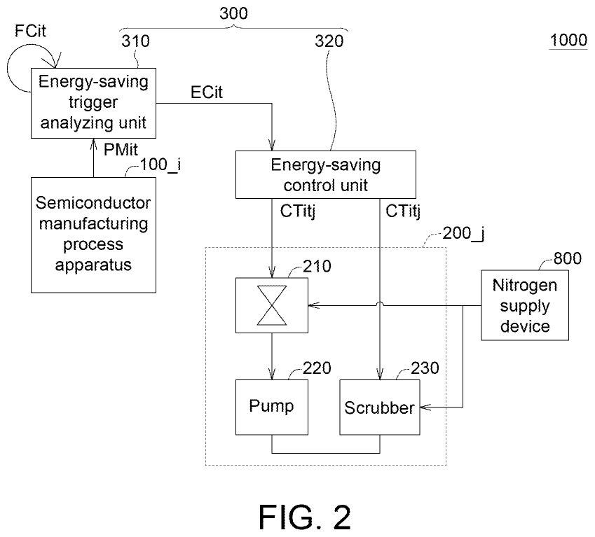

Please refer to FIG. 1 and FIG. 2. FIG. 1 illustrates a controlling method of a semiconductor manufacturing process apparatus 100_i and a semiconductor process auxiliary apparatus 200_j of a manufacturing system 1000 according to an embodiment. FIG. 2 shows a block diagram of the manufacturing system 1000 according to one embodiment. The semiconductor manufacturing process apparatus 100_i is used to perform a semiconductor manufacturing process on a wafer 900. The semiconductor manufacturing process apparatus 100_i is, for example, a lithography apparatus, an etching apparatus, a thin film deposition apparatus or a diffusion apparatus used in the semiconductor manufacturing process. The semiconductor process auxiliary apparatus 200_j is connected to the semiconductor manufacturing process apparatus 100_i to maintain a processing environment of the semiconductor manufacturing process apparatus 100_i. As shown in FIG. 2, the semiconductor process auxiliary apparatus 200_j includes, for example, a nitrogen regulator 210, a pump 220 and a scrubber 230. For example, the pump 220 extracts gas from the chamber of the semiconductor manufacturing process apparatus 100_i to create a vacuum environment. Further, nitrogen gas is provided into the pump 220 to take away the powder produced by condensation of the process exhaust gas. Next, the scrubber 230 is used to purify the toxic/flammable waste gas in the cavity extracted by the pump 220, to process the toxic/flammable waste gas into safe/clean waste gas, and discharge it to the factory system (not shown).

As shown in FIG. 1, the semiconductor manufacturing process apparatus 100_i provides the manufacturing parameter PMit to an energy-saving trigger analyzing unit 310 of a control assembly 300. The energy-saving trigger analyzing unit 310 is, for example, a circuit, a chip, a circuit board or a storage device that stores program code. In one embodiment, the energy-saving trigger analyzing unit 310 may be an Equipment Automation Program (EAP). The energy-saving trigger analyzing unit 310 generates an energy adjusting signal ECit according to the manufacturing parameter PMit of the semiconductor manufacturing process apparatus 100_i.

The energy-saving control unit 320 of the control assembly 300 is used to generate an auxiliary apparatus controlling signal CTitj according to the energy adjusting signal ECit. The energy-saving control unit 320 is, for example, a circuit, a chip, a circuit board or a storage device that stores program codes. The semiconductor process auxiliary apparatus 200_j is controlled according to the auxiliary apparatus controlling signal CTitj, so that the semiconductor process auxiliary apparatus 200_j will not use 100% of the energy consumption or materials all the time.

As shown in FIG. 1, when the semiconductor manufacturing process apparatus 100_i is in a processing phase PS, the semiconductor process auxiliary apparatus 200_j uses higher energy consumption or uses more materials to maintain the processing environment required by the semiconductor manufacturing process apparatus 100_i. When the semiconductor manufacturing process apparatus 100_i is in an idle phase IDL, the semiconductor process auxiliary apparatus 200_j uses lower energy consumption or uses less materials to achieve the effect of saving energy consumption and saving materials.

As shown in the block diagram in FIG. 2, the manufacturing system 1000 includes, for example, the semiconductor manufacturing process apparatus 100_i, the control assembly 300, the semiconductor process auxiliary apparatus 200_j and a nitrogen supply device 800. In this embodiment, during the operation of the semiconductor manufacturing process apparatus 100_i, the energy adjusting signal ECit could be generated according to the manufacturing parameter PMit of the semiconductor manufacturing process apparatus 100_i. Then, the corresponding auxiliary apparatus controlling signal CTitj is generated according to the energy adjusting signal ECit. According to the auxiliary apparatus controlling signal CTitj, the semiconductor process auxiliary apparatus 200_j will not use 100% of the energy consumption or materials all the time and therefore the effect of energy saving or material saving is achieved. The following is a flow chart to explain in detail the operation of each of the above components.

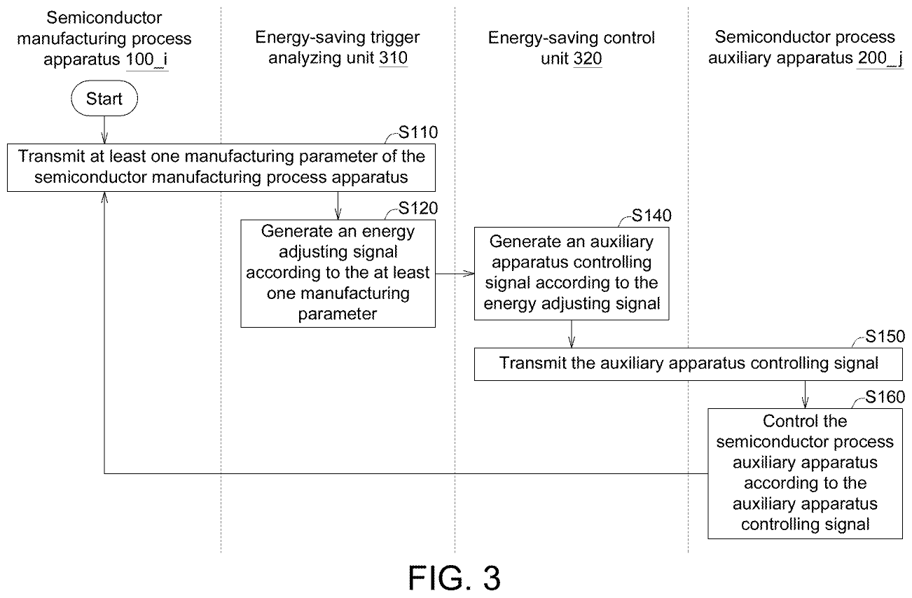

Please refer to FIG. 3, which illustrates a flow chart of a controlling method for the semiconductor process auxiliary apparatus 200_j according to an embodiment. In step S110 of FIG. 3, the energy-saving trigger analyzing unit 310 of the control assembly 300 obtains the manufacturing parameter PMit of the semiconductor manufacturing process apparatus 100_i from the semiconductor manufacturing process apparatus 100_i. The manufacturing parameter PMit includes, for example, an energy setting value, a pressure setting value, a temperature setting value, or a gas valve position. The energy setting value is, for example, the energy of the radio frequency plasma power. The temperature setting value is, for example, the chamber temperature. The pressure setting value is, for example, the chamber pressure. The gas valve position is, for example, the gas valve position between the pump and the chamber. Those examples are not used to limit the present disclosure. The manufacturing parameter PMit of the semiconductor manufacturing process apparatus 100_i is, for example, the content described in Table 1 below.

TABLE I

| STEP | | | | | |
|---|---|---|---|---|---|
| NAME | [A] | [B] | [C] | [D] | [E] |
| Pressure | 0 | 0 | 0 | 3 | 1 |
| Target | | | | | |

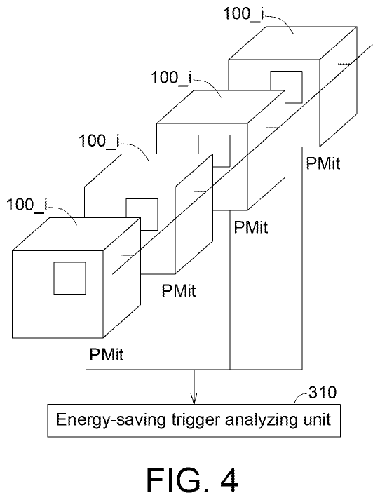

Please refer to FIG. 4, which shows a schematic diagram of the semiconductor manufacturing process apparatus 100_i according to an embodiment. During the semiconductor manufacturing process, a variety of different semiconductor manufacturing process apparatuses 100_i, such as lithography apparatus, etching apparatus, thin film apparatus or diffusion apparatus, need to be used to perform the semiconductor process. Each semiconductor manufacturing process apparatus 100_i could transmit the manufacturing parameters PMit to the energy-saving trigger analyzing unit 310. The semiconductor manufacturing process apparatus 100_i and the energy-saving trigger analyzing unit 310 communicate using, for example, a wireless network, an LTE transmission system, or a wired network.

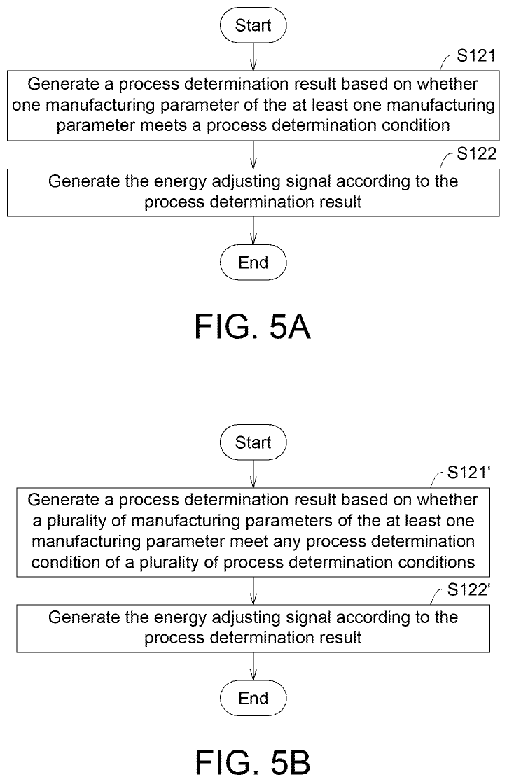

Next, in step S120 of FIG. 3, as shown in FIG. 2, the energy-saving trigger analyzing unit 310 generates the energy adjusting signal ECit according to the manufacturing parameter PMit. Please refer to FIG. 5A, which illustrates a detailed flow chart of step S120 according to an embodiment. For example, the step S120 includes steps S121 to S122. In step S121 of FIG. 5A, as shown in Table 2, the energy-saving trigger analyzing unit 310 generates a process determination result FCit based on whether single manufacturing parameter PMit (for example, “Pressure Target”) meets a process determination condition. For example, the process determination condition is “Pressure Target is greater than 0”. When the value of “Pressure Target” is greater than 0, the process determination result FCit is “1”. When the value of “Pressure Target” is not greater than 0, the process determination result FCit is “0”.

TABLE II

| Pressure | | | | | |
|---|---|---|---|---|---|
| Target | 0 | 0 | 0 | 3 | 1 |
| Process | 0 | 0 | 0 | 1 | 1 |
| determination | | | | | |
| result FCit | | | | | |

Next, in step S122 of FIG. 5A, as shown in FIG. 2, the energy-saving trigger analyzing unit 310 generates the energy adjusting signal ECit according to the process determination result FCit. For example, when the process determination result FCit is “0”, it means that the semiconductor manufacturing process apparatus 100_i is in production and the semiconductor process auxiliary 200_j does not need to be in energy-saving mode, so the energy adjusting signal ECit could be set to “0” and the energy saving is not performed. When the process determination result FCit is “1”, it means that the semiconductor manufacturing process apparatus 100_i is not in production and the semiconductor process auxiliary 200_j needs to be in energy-saving mode, so the energy adjusting signal ECit could be set to “1” to save energy.

In the above-mentioned steps S121 to S122, analysis is performed based on the single manufacturing parameter PMit, and the energy adjusting signal ECit is generated accordingly.

Please refer to FIG. 5B, which illustrates a detailed flow chart of the step S120 according to another embodiment. For example, the step S120 includes steps S121′ to S122′. In step S121′ of FIG. 5B, as shown in FIG. 2, the energy-saving trigger analyzing unit 310 generates a process determination result FCit based on whether multiple manufacturing parameters PMit meet any one of a plurality of process determination conditions.

Next, in the step S122′ of FIG. 5B, as shown in FIG. 2, the energy-saving trigger analyzing unit 310 generates the energy adjusting signal ECit according to the process determination results FCit. In the above steps S121′ to S122′, a plurality of manufacturing parameters are analyzed and the energy adjusting signal ECit is generated accordingly. For example, when any one of the process determination conditions is met and then any process determination result FCit is “1”, it means that the semiconductor manufacturing process apparatus 100_i is not in production and the semiconductor process auxiliary 200_j needs to be in energy-saving mode, so the energy adjusting signal ECit could be set to “1” to perform energy saving. When all the process determination conditions are not met and then all process determination result FCit is “0”, it means that production is in progress and there is no need to save energy on the semiconductor process auxiliary apparatus 200_j, so the energy adjusting signal ECit can be set to “0”, and the energy saving is not performed.

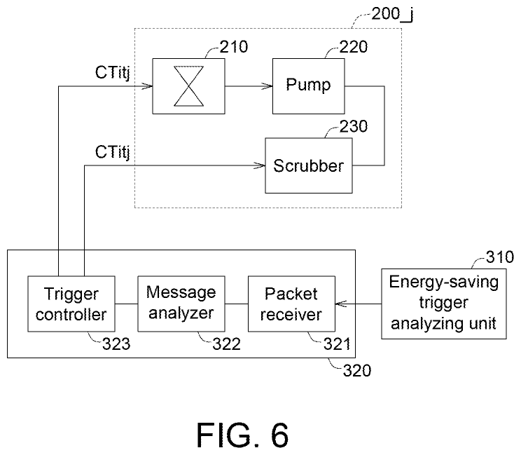

Next, in step S140 of FIG. 3, as shown in FIG. 6, the energy-saving control unit 320 generates the auxiliary apparatus controlling signal CTitj according to the energy adjusting signal ECit. For example, FIG. 6 shows a detailed schematic diagram of the energy-saving control unit 320 according to one embodiment. The energy-saving control unit 320 includes, for example, a packet receiver 321, a message analyzer 322 and a trigger controller 323. The packet receiver 321 is used to receive the energy adjusting signal ECit. The message analyzer 322 is used to analyze the content of the energy adjusting signal ECit to determine which semiconductor process auxiliary apparatus 200_j will be performed in the energy-saving mode. The trigger controller 323 is used to generate the auxiliary apparatus controlling signal CTitj.

Next, in step S150 of FIG. 3, as shown in FIG. 6, the energy-saving control unit 320 transmits the auxiliary apparatus controlling signal CTitj to the semiconductor process auxiliary apparatus 200_j.

Then, in step S160 of FIG. 3, the semiconductor process auxiliary apparatus 200_j is controlled according to the auxiliary apparatus controlling signal CTitj. For example, the nitrogen regulator 210 includes a flow regulating valve. The auxiliary apparatus controlling signal CTitj is used to provide the flow regulating valve switching command or switching actuation voltage of the nitrogen regulator 210 to switch the flow regulating valve to the low flow mode.

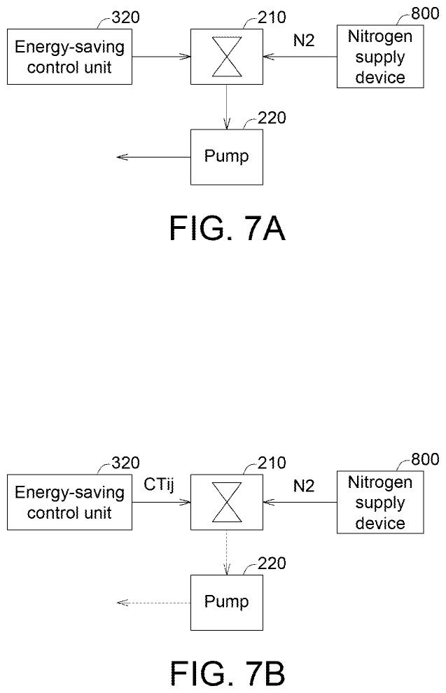

Please refer to FIGS. 7A to 7B, which illustrate the energy-saving control of the nitrogen regulator 210 and the pump 220. The nitrogen supply device 800 introduces nitrogen into the pump 220 through the regulation of the nitrogen regulator 210 to take away the powder produced by the condensation of the process exhaust gas. The pump 220 itself does not have an energy-saving function, but by controlling the nitrogen regulator 210, it can achieve the effect of saving energy consumption and materials. As shown in FIG. 7A, when the energy-saving control unit 320 does not provide the auxiliary apparatus controlling signal CTitj to the nitrogen regulator 210, the flow regulating valve of the nitrogen regulator 210 is in the high flow mode, and the pump 220 provides more nitrogen to the cavity so as to take away the powder produced by condensation of process waste gas.

As shown in FIG. 7B, when the energy-saving control unit 320 provides the auxiliary apparatus controlling signal CTitj to the nitrogen regulator 210, the flow regulating valve of the nitrogen regulator 210 is in the low flow mode, and the pump 220 provides less nitrogen to the cavity to achieve the effect of saving energy consumption and materials.

As another example, the scrubber 230 includes a heating end, a cooling end and a plurality of valves. When the energy-saving control unit 320 does not provide the auxiliary apparatus controlling signal CTitj to the valve, exhaust gas and nitrogen are injected into the heating end, and after being cooled at the cooling end, flow to the exhaust pipe.

When the energy-saving control unit provides the auxiliary apparatus controlling signal CTitj to the valve, the valve controls the nitrogen reduction, and the valve controls the cooling water reduction to achieve the effect of saving energy consumption and materials. The above illustrated examples are not intended to limit the scope and implementation of the present invention.

According to the above embodiment, during the operation of the semiconductor manufacturing process apparatus 100_i, the energy adjusting signal ECit could be generated according to the manufacturing parameter PMit of the semiconductor manufacturing process apparatus 100_i. Then, the corresponding auxiliary apparatus controlling signal CTitj is generated according to the energy adjusting signal ECit. According to the auxiliary apparatus controlling signal CTitj, the semiconductor process auxiliary apparatus 200_j will not use 100% of the energy consumption or materials at all times to achieve the effect of energy saving or material saving.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A controlling method for controlling at least one semiconductor process auxiliary apparatus, comprising:
obtaining at least one manufacturing parameter of a semiconductor manufacturing process apparatus;
generating an energy adjusting signal according to the at least one manufacturing parameter;
generating an auxiliary apparatus controlling signal according to the energy adjusting signal; and
controlling the at least one semiconductor process auxiliary apparatus according to the auxiliary apparatus controlling signal.

2. The controlling method according to claim 1, wherein generating the energy adjusting signal includes:
generating a process determination result based on whether one manufacturing parameter of the at least one manufacturing parameter meets a process determination condition; and
generating the energy adjusting signal according to the process determination result.

3. The controlling method according to claim 1, wherein generating the energy adjusting signal includes:
generating a process determination result based on whether a plurality of manufacturing parameters meet any process determination condition of a plurality of process determination conditions; and
generating the energy adjusting signal according to the process determination result.

4. The controlling method according to claim 1, wherein the at least one manufacturing parameter includes an energy setting value, a temperature setting value, a pressure setting value, or a gas valve position.

5. The controlling method according to claim 1, wherein the semiconductor manufacturing process apparatus is used to perform semiconductor manufacturing processes on wafers, and the at least one semiconductor process auxiliary apparatus is connected to the semiconductor manufacturing process apparatus to provide a processing environment for the semiconductor manufacturing process apparatus.

6. The controlling method according to claim 1, wherein the at least one semiconductor process auxiliary apparatus includes a plurality of semiconductor process auxiliary apparatuses, and the plurality of semiconductor process auxiliary apparatuses perform different controls according to the auxiliary apparatus controlling signal.

7. The controlling method according to claim 1, wherein the semiconductor manufacturing process apparatus is a lithography apparatus, an etching apparatus, a thin film deposition apparatus, or a diffusion apparatus.

8. The controlling method according to claim 1, wherein the at least one semiconductor process auxiliary apparatus is a pump or a scrubber.
